(19) United States
(12) Patent Application Publication
(10) Pub. No.: US 2015/0213845 A1
(43) Pub. Date: Jul. 30, 2015

(54) SYSTEM USING MINIMUM OPERATION POWER AND POWER SUPPLY VOLTAGE SETTING METHOD OF MEMORY DEVICE

(71) Applicant: SK hynix Inc., Icheon-si (KR)

(72) Inventors: Hoon CHOI, Icheon-si (KR); Seung Geun BAEK, Icheon-si (KR)

(73) Assignee: SK hynix Inc., Icheon-si (KR)

(21) Appl. No.: 14/278,895

(22) Filed: May 15, 2014

(30) Foreign Application Priority Data
Jan. 29, 2014 (KR) 10-2014-0011051

(51) Int. Cl. G11C 5/14; G11C 7/22

(52) U.S. Cl. CPC G11C 5/147; G11C 7/22

(57) ABSTRACT

A system includes a memory device, a controller, and a power supply. The controller stores a write data in the memory device, and generates a voltage control signal by comparing a read data outputted from the memory device with the write data. The power supply controls a level of a power supply voltage supplied to the memory device in response to the voltage control signal.

### CROSS-REFERENCES TO RELATED APPLICATION

The present application claims priority under 35 U.S.C. §119(a) to Korean application number 10-2014-0011051, filed on Jan. 29, 2014 in the Korean Intellectual Property Office, which is incorporated herein by reference in its entirety as set forth in full.

### BACKGROUND

1. Technical Field

Various embodiments generally relate to a system circuit, and more particularly, to a system using minimum operation power and a power supply voltage setting method of a memory device.

2. Related Art

In general, an electronic system is provided with a power supply voltage through a power supply. As illustrated in FIG. 1, the system 10 may include a controller 11, first to n memory devices 12-1, 12-2, and 12-n (where n may be zero or a natural number greater than 2 in this case), and a power supply 13. The controller 11 is configured to perform data communication (i.e., DATA1, DATA2, DATAn (where n may be zero or a natural number greater than 2 in this case)) with the first to n memory devices 12-1, 12-2, and 12-n. The first to n memory devices 12-1, 12-2, and 12-n are configured to operate with power supply voltages PV1, PV2, and PVn (where n may be zero or a natural number greater than 2 in this case) supplied by the power supply 13. The power supply 13 is configured to generate the power supply voltages PV1, PV2, and PVn used by the first to n memory devices 12-1, 12-2, and 12-n.

Referring to the components of system 10 in general, the controller 11, the first to n memory devices 12-1, 12-2, and 12-n, and the power supply 13, are each provided by a different manufacturer or provider. Due to the fact that there are different manufacturers or providers for each of the components the power supply 13 must be designed to generate power supply voltages PV1, PV2, and PVn having a predetermined margin taking into consideration the various operational conditions of the controller 11 or the first to n memory devices 12-1, 12-2, and 12-n. These operational conditions may include manufacturing characteristics, product types, PVT parameters, and skews.

### SUMMARY

In an embodiment, a system may include a memory device, and a controller configured to store a write data in the memory device, and configured to generate a voltage control signal by comparing a read data outputted from the memory device with the write data. The system may also include a power supply configured to control a level of a power supply voltage supplied to the memory device in response to the voltage control signal.

In an embodiment, a system may include a plurality of memory devices, and a controller configured to store a write data in the plurality of memory devices, and configured to generate a plurality of voltage control signals by comparing each of a plurality of read data outputted from the plurality of memory devices with the write data. The system may also incudes a power supply configured to control each of levels of a plurality of power supply voltages supplied to the plurality of memory devices in response to the plurality of voltage control signals.

In an embodiment, a system may include a memory module including a plurality of memory devices, and a controller configured to store a write data in the memory module, and configured to generate a voltage control signal by comparing a plurality of read data outputted from the memory module with the write data. The system may also include a power supply configured to control a level of a power supply voltage supplied to the memory module in response to the voltage control signal.

In an embodiment, a power supply voltage setting method of a memory device may include transmitting data from a controller to the memory device, and storing the data in the memory device, and outputting data stored in the memory device. The power supply voltage setting method of a memory device may also include comparing the data transmitted to the memory device with the data outputted from the memory device, and controlling a level of a power supply voltage supplied to the memory device according to a result of the comparing of the data transmitted to the memory with the data outputted from the memory device.

### BRIEF DESCRIPTION OF THE DRAWINGS

FIG. 1 is a block diagram illustrating a representation of a conventional system.

FIG. 2 is a block diagram representation of a system in accordance with an embodiment.

FIG. 3 is a circuit diagram representation of a data comparison unit illustrated in FIG. 2.

FIG. 4 is a flow chart representation of an operation of a system and a power supply voltage setting method of memory device in accordance with an embodiment.

FIG. 5 is a block diagram representation of a system in accordance with an embodiment.

FIG. 6 is a circuit diagram representation of a data comparison unit illustrated in FIG. 5.

FIG. 7 illustrates a block diagram representation of a general system employing the system in accordance with the embodiments discussed above with relation to FIGS. 1-6.

### DETAILED DESCRIPTION

Hereinafter, a semiconductor apparatus according to the present invention will be described below with reference to the accompanying drawings through various examples of embodiments.

Controlling the voltage level of a power supply voltage according to the characteristics of a memory device or other devices within the system (i.e, controller) may reduce power consumption of the system. This in turn may increase the mobility of the system, promote echo-friendly features related to power consumption, and reduce economic costs associated with the system.

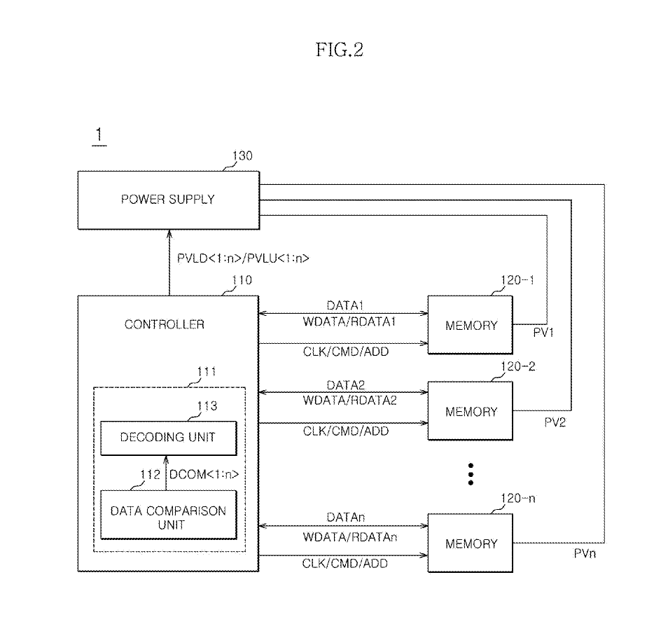

Referring now to FIG. 2, the system 1 in accordance with an embodiment may include a controller 110, one or more memory devices 120-1, 120-2, and 120-n (where n may be zero or a natural number greater than 2 in these embodiments), and a power supply 130. The system 1 may include one or more memory devices. For example though, FIG. 2 shows that system 1 includes a plurality of memory devices 120-1, 120-2, and 120-n . The controller 110 and each of the plurality of memory devices 120-1, 120-2, and 120-n may perform communication using a plurality of buses. The plurality of buses may include a data bus, a clock bus, and a data strobe bus. The plurality of buses may also include a command bus, and an address bus. The controller 110 may provide data DATA1, DATA2, and DATAn (where n may be zero or a natural number greater than 2 in these embodiments), a clock signal CLK, a command signal CMD, and an address signal ADD through the buses to allow each of the memory devices 120-1, 120-2, and 120-n to store data DATA1, DATA2, and DATAn. Also, the controller 110 may provide a clock signal CLK, a command signal CMD, and an address signal ADD to each of the memory devices 120-1, 120-2, and 120-n. The controller 110 may also receive data DATA1, DATA2, and DATAn outputted from the plurality of memory devices 120-1, 120-2, and 120-n. Each of the memory devices 120-1, 120-2, and 120-n may receive the signals CLK, CMD, and ADD from the controller 110 through the buses, store data DATA1, DATA2, and DATAn, and output data DATA1, DATA2, and DATAn, which are stored therein, to the controller 110.

The controller 110 may be, for example, a memory controller or a host apparatus. The memory controller or the host apparatus may include, for example, a Central Processing Unit (CPU), a Graphic Processing Unit (GPU), a Digital Signal Processor (DSP), to one or more process cores, a single core processor, a dual core processor, a multiple core processor, a micro-processor, a host processor, a controller, a plurality of processors or controllers, a chip, a micro-chip, a logic circuit, an integrated circuit (IC), or an application-specific IC, etc.

The memory devices 120-1, 120-2, and 120-n may include, for example, a volatile random access memory apparatus such as a dynamic random access memory device (DRAM), and a non-volatile random access memory apparatus such as a Phase Change Random Access Memory device (PCRAM), a Resistive Random Access Memory device (ReRAM), a Ferroelectric Random Access Memory device (FeRAM), a Magnetic Random Access Memory device (MRAM) and a Spin Transfer Torque Random Access Memory device (STTRAM), etc. The memory devices 120-1, 120-2, and 120-n may be random access memory apparatuses of the same type or random access memory apparatuses of different types.

As illustrated in FIG. 2, the controller 110 may determine whether or not the memory devices 120-1, 120-2, and 120-n are working properly or as planned. The controller 110 may decrease levels of the power supply voltages PV1, PV2, and PVn supplied to the memory devices 120-1, 120-2, and 120-n when the memory devices 120-1, 120-2, and 120-n are working properly. The controller 110 may increase levels of the power supply voltages PV1, PV2, and PVn supplied to the memory devices 120-1, 120-2, and 120-n when the memory devices 120-1, 120-2, and 120-n are not properly working or to not working as planned. The controller 110 may continue decreasing the levels of the power supply voltages PV1, PV2, and PVn when the memory devices 120-1, 120-2, and 120-n continue to work properly with the lowered levels of the power supply voltages PV1, PV2, and PVn. The controller 110 may continue decreasing the levels of the power supply voltages PV1, PV2, and PVn until the memory devices 120-1, 120-2, and 120-n do not work properly with the lowered levels of the power supply voltages PV1, PV2, and PVn. In this way, each of the plurality of memory devices 120-1, 120-2, and 120-n may receive a minimum level of power supply voltages PV1, PV2, and PVn to work properly. Thus, the operational power of the system 1 may be minimized.

in order to determine whether or not the plurality of memory devices 120-1, 120-2, and 120-n are working properly, the controller 110 may allow each of the plurality of memory devices 120-1, 120-2, and 120-n to store data DATA1, DATA2, and DATA3. The plurality of memory devices 120-1, 120-2, and 120-n may store the data DATA1, DATA2, and DATAn transmitted from the controller 110. Also, the plurality of memory devices 120-1, 120-2, and 120-n may output the data DATA1, DATA2, and DATAn, which are stored therein, to the controller 110. The controller 110 may generate a voltage control signal by comparing the data DATA1, DATA2, and DATAn, which are transmitted to be stored in the memory devices 120-1, 120-2, and 120-n, with the data DATA1, DATA2, and DATAn, which are outputted from the memory devices 120-1, 120-2, and 120-n. In this description, a write data WDATA may be transmitted from the controller 110 to the memory devices 120-1, 120-2, and 120-n so that the write data WDATA may be stored in the memory devices 120-1, 120-2, and 120-n, and read data RDATA1, RDATA2, and RDATAn (where n may be zero or a natural number greater than 2 in these embodiments) may be outputted from the memory devices 120-1, 120-2, and 120-n to the controller 110. The data DATA1, DATA2, and DATAn transmitted from the controller 110 to the memory devices 120-1, 120-2, and 120-n may be the same data, which is the write data WDATA. As an example, the data DATA1, DATA2, and DATAn transmitted to the memory devices 120-1, 120-2, and 120-n may be different from one another.

The controller 110 may generate the voltage control signal by comparing the write data WDATA with the plurality of read data RDATA1, RDATA2, and RDATAn received from the memory devices 120-1, 120-2, and 120-n, respectively.

The power supply 130 may provide the power supply voltages PV1, PV2, and PVn to the plurality of memory devices 120-1, 120-2, and 120-n. The power supply voltages PV1, PV2, and PVn may be operational powers for operation of the plurality of memory devices 120-1, 120-2, and 120-n. The power supply 130 may generate each of the power supply voltages PV1, PV2, and PVn for each of the memory devices 120-1, 120-2, and 120-n. The power supply 130 may provide the power supply voltages PV1, PV2, and PVn, which have initially set levels, to the plurality of memory devices 120-1, 120-2, and 120-n. Also, the power supply 130 may provide the power supply voltages PV1, PV2, and PVn. The levels of the power supply voltages PV1, PV2, and PVn may be controlled by the voltage control signal. For example, the power supply 130 may generate the power supply voltages PV1, PV2, and PVn, the levels of which may be increased or decreased by the voltage control signal. In an embodiment, the power supply 130 may provide a power supply voltage for the operation of the controller 110.

Referring to FIG. 2, the controller 110 may include a voltage control unit 111. The voltage control unit 111 may generate the voltage control signal by comparing the write data WDATA with the plurality of read data RDATA1, RDATA2, and RDATAn outputted from the plurality of memory devices 120-1, 120-2, and 120-n, respectively. The voltage control signal may include bits. The number of bits may correspond to the number of the memory devices 120-1, 120-2, and 120-n, in order to control the levels of the power supply voltages PV1, PV2, and PVn for each of the memory devices 120-1, 120-2, and 120-n. The voltage control signal may include a level decrease signal PVLD<1:n>. The voltage control signal may include a level increase signal PVLU<1:n>. The level decrease signal PVLD<1:n> may be used for decreasing the levels of the power supply voltages PV1, PV2, and PVn by a predetermined amount. The level increase signal PVLU<1:n> may be used for increasing the levels of the power supply voltages PV1, PV2, and PVn by a predetermined amount. The power supply 130 may decrease the levels of the power supply voltages PV1, PV2, and PVn by predetermined amounts in response to the level decrease signal PVLD<1:n>. The power supply 130 may increase the levels of the power supply voltages PV1, PV2, and PVn by the predetermined amounts in response to the level increase signal PVLU<1:n>.

The voltage control unit 111 may determine whether or not the memory devices 120-1, 120-2, and 120-n are working properly. The voltage control unit 111 may generate the level decrease signal PVLD<1:n> in order to decrease the levels of the power supply voltages PV1, PV2, and PVn when it is determined that the memory devices 120-1, 120-2, and 120-n are working properly. The voltage control unit 111 may generate the level increase signal PVLU<1:n> in order to increase the levels of the power supply voltages PV1, PV2, and PVn when it is determined that the memory devices 120-1, 120-2, and 120-n are not working properly.

The voltage control unit 111 may compare the write data WDATA with the plurality of read data RDATA1, RDATA2, and RDATAn received from the plurality of memory devices 120-1, 120-2, and 120-n, respectively, and generate the level decrease signal PVLD<1:n> when the plurality of read data RDATA1, RDATA2, and RDATAn are substantially the same as the write data WDATA. Also, the voltage control unit 111 may generate the level increase signal PVLU<1:n> when the plurality of read data RDATA1, RDATA2, and RDATAn are different from the write data WDATA.

As illustrated in FIG. 2, the voltage control unit 111 may include a data comparison unit 112. Referring to FIG. 2, the voltage control unit 111 may also include a decoding unit 113. The data comparison unit 112 may generate a data comparison signal DCOM<1:n> by comparing the write data WDATA with the plurality of read data RDATA1, RDATA2, and RDATAn received from the plurality of memory devices 120-1, 120-2, and 120-n, respectively. The data comparison signal DCOM<1:n> may include bits, the number of bits may correspond to the number of memory devices 120-1, 120-2, and 120-n. For example, data comparison unit 112 may output the data comparison signal DCOM<1:n> having a logic level ‘0’ for the memory devices 120-1, 120-2, and 120-n, which may output the plurality of read data RDATA1, RDATA2, and RDATAn substantially the same as the write data WDATA. For example, data comparison unit 112 may output the data comparison signal DCOM<1:n> having a logic level ‘1’ for the memory devices 120-1, 120-2, and 120-n, which may output the plurality of read data RDATA1, RDATA2, and RDATAn different from the write data WDATA.

The decoding unit 113 may receive the data comparison signal DCOM<1:n> from the data comparison unit 112. The decoding unit 113 may generate the voltage control signal based on the data comparison signal DCOM<1:n>. For example, the decoding unit 113 may generate the level decrease signal PVLD<1:n> based on the data comparison signal DCOM<1:n> having the logic level ‘0’. For example, the decoding unit 113 may generate the level increase signal PVLU<1:n> based on the data comparison signal DCOM<1:n> having the logic level ‘1’. In an example of an embodiment, the decoding unit 113 may be omitted, and the data comparison signal DCOM<1:n>, which are generated by the data comparison unit 112, may be used as the voltage control signal.

In response to the level decrease signal PVLD<1:n> and the level increase signal PVLU<1:n> the power supply 130 may decrease or increase each level of the power supply voltages PV1, PV2, and PVn supplied to the plurality of memory devices 120-1, 120-2, and 120-n. The power supply 130 may include a voltage trimming unit configured to decrease or increase the levels of the power supply voltages PV1, PV2, and PVn by the predetermined amounts in response to the level decrease signal PVLD<1:n> and the level increase signal PVLU<1:n>. For example, the power supply 130 may generate the power supply voltages PV1, PV2, and PVn. The levels of the power supply voltages PV1, PV2, and PVn may gradually decrease by the predetermined amount whenever the power supply 130 receives the level decrease signal PVLD<1:n>. The power supply 130 may generate the power supply voltages PV1, PV2, and PVn. The levels of the power supply voltages PV1, PV2, and PVn may gradually increase by the predetermined amount whenever the power supply 130 receives the level increase signal PVLU<1:n>.

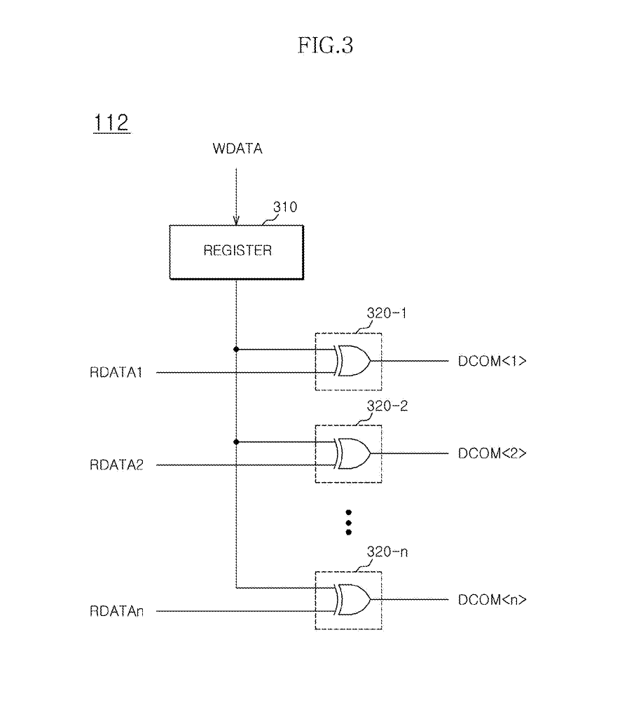

FIG. 3 is a circuit diagram representation of the data comparison unit 112 illustrated in FIG. 2. Referring to FIG. 3, the data comparison unit 112 may include a register 310. The data comparison unit 112 may also include a plurality of comparators 320-1, 320-2, and 320-n (where n may be zero or a natural number greater than 2 in these embodiments). The register 310 may store the write data WDATA. The register 310 may store the write data WDATA in order that the write data WDATA may be compared with the read data RDATA1, RDATA2, and RDATAn (where n may be zero or a natural number greater than 2 in these embodiments).

The plurality of comparators 320-1, 320-2, and 320-n may receive the write data WDATA stored in the register 310, and each of the read data RDATA1, RDATA2, and RDATAn outputted from the plurality of memory devices 120-1, 120-2, and 120-n. The plurality of comparators 320-1, 320-2, and 320-n may generate the data comparison signal DCOM<1:n> (where n may be zero or a natural number greater than 2 in these embodiments) by comparing the write data WDATA with each of the read data RDATA1, RDATA2, and RDATAn. Each of the plurality of comparators 320-1, 320-2, and 320-n may include, for example, a XOR gate. Each of the XOR gates may receive the write data WDATA and each of the read data RDATA1, RDATA2, and RDATAn, and output the data comparison signal DCOM<1:n>. The plurality of comparators 320-1, 320-2, and 320-n each comprising the XOR gate may output the data comparison signal DCOM<1:n> having the logic level ‘0’ for the memories 120-1, 120-2, and 120-n, which may output the plurality of read data RDATA1, RDATA2, and RDATAn substantially the same as the write data WDATA. The plurality of comparators 320-1, 320-2, and 320-n each comprising the XOR gate may output the data comparison signal DCOM<1:n> having the logic level ‘1’ for the memory devices 120-1, 120-2, and 120-n, which may output the plurality of read data RDATA1, RDATA2, and RDATAn different from the write data WDATA.

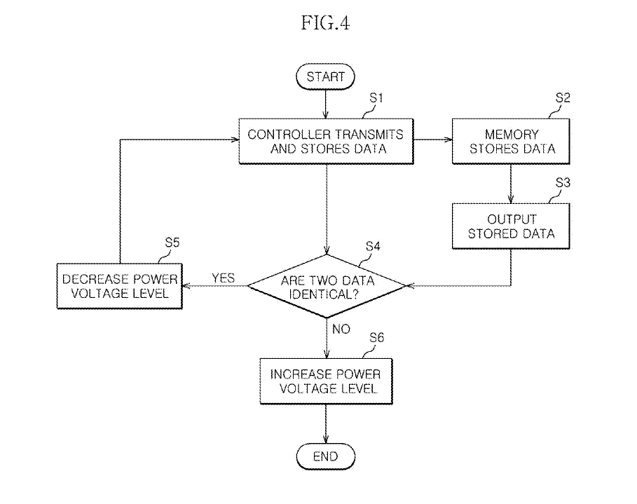

FIG. 4 is a flow chart representing the operation of the system 1 and a power supply voltage setting method of the memory devices 120-1, 120-2, and 120-n in accordance with an embodiment. The operation of the system 1 and the power supply voltage setting method of memory devices 120-1, 120-2, and 120-n will be described with reference to FIGS. 2 to 4 below. In step S1, the controller 110 may transmit data to the memory devices 120-1, 120-2, and 120-n so that the controller 110 may determine whether or not the memory devices 120-1, 120-2, and 120-n are working properly. Also in step S1, the controller 110 may decrease the levels of the power supply voltages PV1, PV2, and PVn used by the memory devices 120-1, 120-2, and 120-n. In step S1, the controller 110 may store the data transmitted to the memory devices 120-1, 120-2, and 120-n, and, in step S2, the memory devices 120-1, 120-2, and 120-n may store the data transmitted from the controller 110. After that, in step S3, the memory devices 120-1, 120-2, and 120-n may output the stored data to the controller 110.

In step S4, the controller 110 may compare the data stored in the register 310 with the data outputted from the memory devices 120-1, 120-2, and 120-n through the data comparison unit 112 of the voltage control unit 111. In step S4 the data outputted from the memory devices 120-1, 120-2, and 120-n are compared with the data stored in the register 310. Thus, when the data outputted from the memory devices 120-1, 120-2, and 120-n are substantially the same as the data stored in the register 310 (i.e., YES), in step S5, the controller 110 may generate the level decrease signal PVLD<1:n> and the power supply 130 may decrease the levels of the power supply voltages PV1, PV2, and PVn supplied to the memory devices 120-1, 120-2, and 120-n. Steps S1 to S5 may be repeated until the data outputted from the memory devices 120-1, 120-2, and 120-n are different from the data stored in the register 310 (i.e., NO).

When the data outputted from the memory devices 120-1, 120-2, and 120-n are different from the data stored in the register 310 as the level of the power supply voltages PV1, PV2, and PVn decrease, the controller 110, as indicated by step 6 in FIG. 4, may generate the level increase signal PVLU<1:n>. The power supply 130 may increase the levels of the power supply voltages PV1, PV2, and PVn supplied to the memory devices 120-1, 120-2, and 120-n and the power supply voltage setting method of the memory devices 120-1, 120-2, and 120-n may then be ended, as indicated by the step END. Therefore, each of the plurality of memory devices 120-1, 120-2, and 120-n may operate with the minimum level of power supply voltages PV1, PV2, and PVn while maintaining normal operation of the memory devices 120-1, 120-2, and 120-n. In this way, the operational power of the system 1 may be minimized.

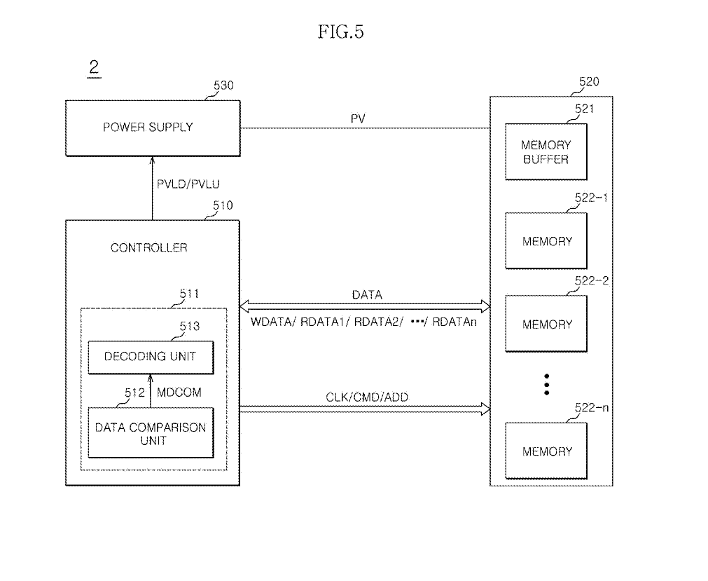

FIG. 5 is a block diagram representation of a system 2 in accordance with an embodiment. Referring to FIG. 5, the system 2 to may include a controller 510, and a memory module 520. The system 2 may also include a power supply 530. The memory module 520 may include a plurality of memory devices 522-1, 522-2, and 522-n (where n may be zero or a natural number greater than 2 in these embodiments 2). Also, the memory module 520 may include a memory buffer 521. The memory buffer 521 may be configured to communicate with the controller 510. The memory buffer 521 may be an interface chip configured to couple the controller 510 with the memory devices 522-1, 522-2, and 522-n. Data DATA, a clock signal CLK, a command signal CMD, and an address signal ADD, which are transmitted from the controller 510 to the memory module 520, may be transferred to each of the memory devices 522-1, 522-2, and 522-n through the memory buffer 521. Data DATA that is outputted from the memory devices 522-1, 522-2, and 522-n, may be transferred to the controller 510 through the memory buffer 521.

The controller 510 may determine whether or not the memory module 520 is working properly so that the memory module 520 may operate with the minimum operational power needed. The controller 510 may decrease the level of the power supply voltage PV when the memory module 520 is working properly. The controller 510 may increase the level of the power supply voltage PV when the memory module 520 is not working properly. The controller 510 may decrease the level of the power supply voltage PV supplied to the memory module 520 when all of the plurality of memory devices 522-1, 522-2, and 522-n included in the memory module 520 are working properly. The controller 510 may increase the level of the power supply voltage PV supplied to the memory module 520 when one or more of the plurality of memory devices 522-1, 522-2, and 522-n do not work properly. The same power supply voltage PV supplied to the memory module 520 may be used as the power supply voltage for each of the plurality of memory devices 522-1, 522-2, and 522-n. Thus, the power supply voltage PV supplied to the memory module 520 may be substantially the same as the power supply voltage used for the memory device 522-1, 522-2, and/or 522-n.

The controller 510 may transmit the data DATA to the memory module 520, and the memory module 520 may store the data DATA. The data DATA may be received by the controller through the memory buffer 521 and stored into each of the memory devices 522-1, 522-2, and 522-n. After that, the data DATA stored in the memory devices 522-1, 522-2, and 522-n may be outputted to the controller 510 through the memory buffer 521. In this description, a write data WDATA may be transmitted from the controller 510 to the memory module 520, and read data RDATA1, RDATA2, and RDATAn (where n may be zero or a natural number greater than 2 in these embodiments 2) may be outputted from each of the memories 522-1, 522-2, and 522-n through the memory buffer 510.

The controller 510 may include a voltage control unit 511. The voltage control unit 511 may generate a voltage control signal by comparing the write data WDATA with the read data RDATA1, RDATA2, and RDATAn outputted from the memory devices 522-1, 522-2, and 522-n. The voltage control signal may include either a level decrease signal PVLD or a level increase signal PVLU. The voltage control unit 511 may generate the level decrease signal PVLD when each of the read data RDATA1, RDATA2, and RDATAn outputted from each of the plurality of memory devices 522-1, 522-2, and 522-n are substantially the same as the write data WDATA. The voltage control unit 511 may generate the level increase signal PVLU when one or more of the read data RDATA1, RDATA2, and RDATAn outputted from the plurality of memory devices 522-1, 522-2, and 522-n are different from the write data WDATA.

The voltage control unit 511 may include a data comparison unit 512 and a decoding unit 513. The data comparison unit 512 may generate a module data comparison signal MDCOM by comparing the write data WDATA with the read data RDATA1, RDATA2, and RDATAn outputted from the plurality of memory devices 522-1, 522-2, and 522-n, respectively. For example, data comparison unit 512 may generate the module data comparison signal MDCOM having a logic level ‘0’ when the plurality of read data RDATA1, RDATA2, and RDATAn are substantially the same as the write data WDATA. Also for example, the data comparison unit 512 may generate the module data comparison signal MDCOM having a logic level ‘1’ when one or more of the plurality of read data RDATA1, RDATA2, and RDATAn are different from the write data WDATA. The decoding unit 513 may generate the voltage control signal based on the module data comparison signal MDCOM. For example, the decoding unit 513 may generate the level decrease signal PVLD based on the module data comparison signal MDCOM having the logic level ‘0’. Also for example, the decoding unit 513 may generate the level increase signal PVLU based on the module data comparison signal MDCOM having the logic level ‘1’. In an embodiment, the decoding unit 513 may be omitted, and the module data comparison signal MDCOM may be used in place of the voltage control signal but operating substantially the same as the voltage control signal.

The power supply 530 may control the level of the power supply voltage PV supplied to the memory module 520 in response to the voltage control signal. The power supply 530 may decrease the level of the power supply voltage PV supplied to the memory module 520 when the power supply 530 receives the level decrease signal PVLD from the controller 510. The power supply 530 may increase the level of the power supply voltage PV supplied to the memory module 520 when the power supply 530 receives the level increase signal PVLU from the controller 510.

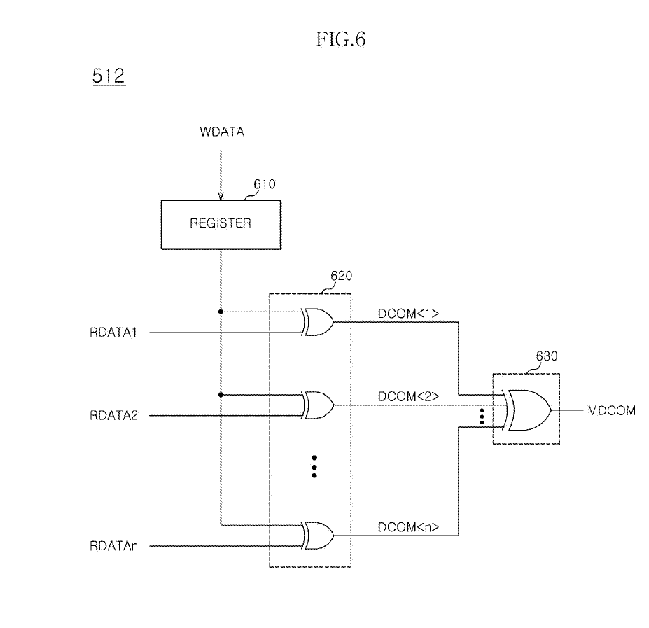

FIG. 6 is a circuit diagram representing an example of the data comparison unit 512 illustrated in FIG. 5. Referring to FIG. 6, the data comparison unit 512 may include a register 610 and a first comparator 620. The data comparison unit 512 may also include a second comparator 630. The register 310 may store the write data WDATA. The first comparator 620 may generate a first comparison signal DCOM<1:n> (where n may be zero a natural number greater than 2 in these embodiments) by comparing the write data WDATA outputted from the register 610 with each of the read data RDATA1, RDATA2, and RDATAn outputted from the plurality of memory devices 522-1, 522-2, and 522-n. The second comparator 630 may generate the module data comparison signal MDCOM based on the first comparison signal DCOM<1:n>.

The first comparator 620 may include one or more XOR gates. Each of the XOR gates may receive the write data WDATA and each read data RDATA1, RDATA2, and RDATAn, respectively, and generate the first comparison signal DCOM<1:n>. Therefore, the first comparator 620 may generate the first comparison signal DCOM<1:n> having the logic level ‘0’ when each of the plurality of read data RDATA1, RDATA2, and RDATAn are substantially the same as the write data WDATA. Additionally, the first comparator 620 may generate the first comparison signal DCOM<1:n> having the logic level ‘1’ when one or more of the plurality of read data RDATA1, RDATA2, and RDATAn are different from the write data WDATA. The second comparator 630 may also include a XOR gate. The XOR gate may receive the first comparison signal DCOM<1:n>, and generate the module data comparison signal MDCOM. The second comparator 630 may generate the module data comparison signal MDCOM having a logic level of ‘0’ when all of the first comparison signal DCOM<1:n> have the logic level ‘0’. The second comparator 630 may generate the module data comparison signal MDCOM having a logic level of ‘1’ when one or more of the first comparison signal DCOM<1:n> have the logic level ‘1’.

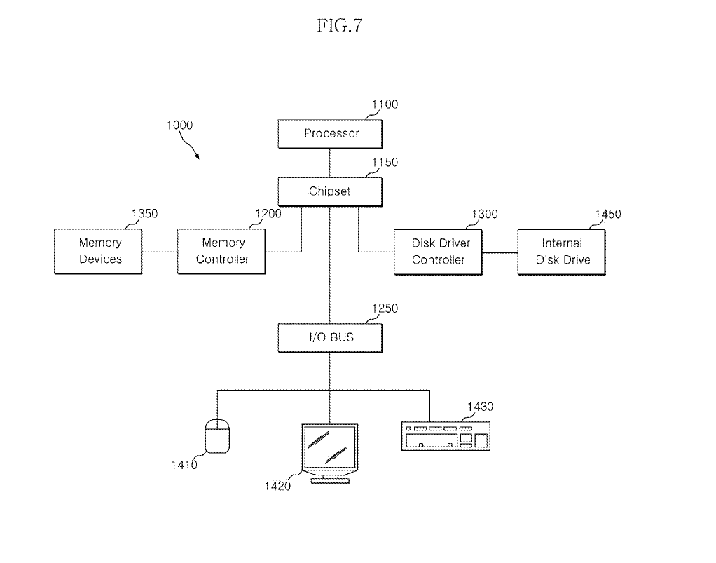

The system discussed above is particular useful in the design of memory devices, processors, and computer systems. For example, referring to FIG. 7, a block diagram of a general system employing the system in accordance with the embodiments are illustrated and generally designated by a reference numeral 1000. The general system 1000 may include one or more processors or central processing units (“CPUs”) 1100. The CPU 1100 may be used individually or in combination with other CPUs. While the CPU 1100 will be referred to primarily in the singular, it will be understood by those skilled in the art that a system with any number of physical or logical CPUs may be implemented.

A chipset 1150 may be operably coupled to the CPU 1100. The chipset 1150 is a communication pathway for signals between the CPU 1100 and other components of the general system 1000, which may include a memory controller 1200, an input/output (“I/O”) bus 1250, and a disk drive controller 1300. Depending on the configuration of the general system 1000, any one of a number of different signals may be transmitted through the chipset 1150, and those skilled in the art will appreciate that the routing of the signals throughout the general system 1000 can be readily adjusted without changing the underlying nature of the general system 1000.

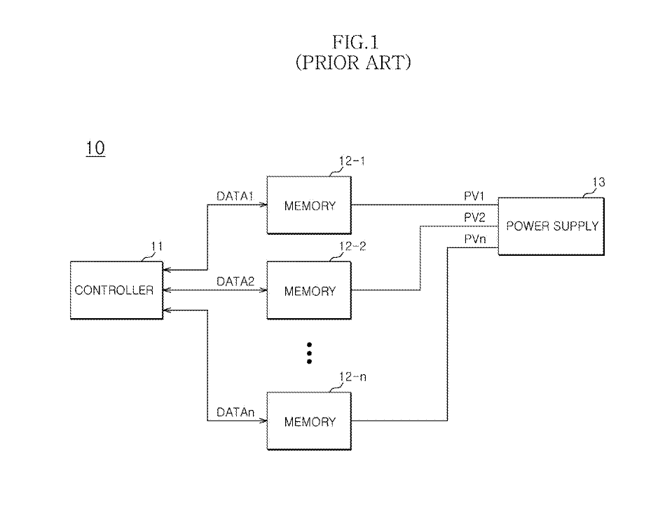

As stated above, the memory controller 1200 may be operably coupled to the chipset 1150. The memory controller 1200 may include at least one system or controller 110 or 510 as discussed above with reference to FIGS. 1-6. Thus, the memory controller 1200 can receive a request provided from the CPU 1100, through the chipset 1150. In alternate embodiments, the memory controller 1200 may be integrated into the chipset 1150. The memory controller 1200 may be operably coupled to one or more memory devices 1350. In an embodiment, the memory devices 1350 may include the system or memory 120-n or 522-n as discussed above with relation to FIGS. 1-6, the memory devices 1350 may include a plurality of word lines and a plurality of bit lines for defining a plurality of memory cell. The memory devices 1350 may be any one of a number of industry standard memory types, including but not limited to, single inline memory modules (“SIMMs”) and dual inline memory modules (“DIMMs”). Further, the memory devices 1350 may facilitate the safe removal of the external data storage devices by storing both instructions and data.

The chipset 1150 may also be coupled to the I/O bus 1250. The I/O bus 1250 may serve as a communication pathway for signals from the chipset 1150 to I/O devices 1410, 1420 and 1430. The I/O devices 1410, 1420 and 1430 may include a mouse 1410, a video display 1420, or a keyboard 1430. The I/O bus 1250 may employ any one of a number of communications protocols to communicate with the I/O devices 1410, 1420, and 1430. Further, the I/O bus 1250 may be integrated into the chipset 1150.

The disk drive controller 1450 (i.e., internal disk drive) may also be operably coupled to the chipset 1150. The disk drive to controller 1450 may serve as the communication pathway between the chipset 1150 and one or more internal disk drives 1450. The internal disk drive 1450 may facilitate disconnection of the external data storage devices by storing both instructions and data. The disk drive controller 1300 and the internal disk drives 1450 may communicate with each other or with the chipset 1150 using virtually any type of communication protocol, including all of those mentioned above with regard to the I/O bus 1250.

It is important to note that the general system 1000 described above in relation to FIG. 7 is merely one example of a general system employing the system as discussed above with relation to FIGS. 1-6. In alternate embodiments, such as cellular phones or digital cameras, the components may differ from the embodiments shown in FIG. 7.

While certain embodiments have been described above, it will be understood to those skilled in the art that the embodiments described are by way of example only. Accordingly, the system using minimum operation power and the power supply voltage setting method of memory should not be limited based on the described embodiments. Rather, the system using minimum operation power and the power supply voltage setting method of memory described herein should only be limited in light of the claims that follow when taken in conjunction with the above description and accompanying drawings.

What is claimed is:

1. A system comprising:
a memory device;
a controller configured to store write data in the memory device, and configured to generate a voltage control signal by comparing read data outputted from the memory device with the write data; and
a power supply configured to control a level of a power supply voltage supplied to the memory device in response to the voltage control signal.

2. The system of claim 1, wherein the voltage control signal includes a level decrease signal or a level increase signal, and
wherein the controller includes a voltage control unit configured to generate the level decrease signal when the read data is substantially the same as the write data, and generate the level increase signal when the read data is different from the write data.

3. The system of claim 2, wherein the power supply is configured to decrease the level of the power supply voltage supplied to the memory device in response to the level decrease signal.

4. The system of claim 2, wherein the power supply is configured to increase the level of the power supply voltage supplied to the memory device in response to the level increase signal.

5. The system of claim 2, wherein the voltage control unit comprises:
a data comparison unit configured to generate a data comparison signal by comparing the write data with the read data; and
a decoding unit configured to generate the level decrease signal and the level increase signal based on the data comparison signal.

6. The system of claim 5, wherein the data comparison unit comprises:
a register configured to store the write data; and
a comparator configured to generate the data comparison signal by comparing the write data outputted from the register with the read data.

7. The system of claim 1, further comprising one or more memories,
wherein the controller is configured to store the write data in the one or more memories, and is configured to further generate the voltage control signals for the one or more memory devices by comparing each of the read data outputted from the one or more memories with the write data, and
wherein the power supply controls levels of the power supply voltages supplied to the one or more memories in response to the voltage control signals for the one or more memories.

8. The system of claim 7, wherein each of the voltage control signals for the one or more memory devices includes a level decrease signal and a level increase signal, and
wherein the controller includes a voltage control unit configured to generate the level decrease signal when the read data is substantially the same as the write data, and generate the level to increase signal when the read data is different from the write data.

9. The system of claim 8, wherein the power supply is configured to decrease the level of the power supply voltage supplied to the memory devices in response to the level decrease signal.

10. The system of claim 8, wherein the power supply is configured to increase the level of the power supply voltage supplied to the memory devices in response to the level increase signal.

11. A system comprising:
a memory module including a plurality of memory devices;
a controller configured to store write data in the memory module, and configured to generate a voltage control signal by comparing a plurality of read data outputted from the memory module with the write data; and
a power supply configured to control a level of a power supply voltage supplied to the memory module in response to the voltage control signal.

12. The system of claim 11, wherein the voltage control signal includes a level decrease signal or a level increase signal, and
wherein the controller includes a voltage control unit configured to generate the level decrease signal when the plurality of read data are substantially the same as the write data, and configured to generate the level increase signal when one or more of the plurality of read data are different from the write data.

13. The system of claim 12, wherein the power supply is configured to decrease the level of the power supply voltage supplied to the memory device in response to the level decrease signal.

14. The system of claim 12, wherein the power supply is configured to increase the level of the power supply voltage supplied to the memory device in response to the level increase signal.

15. The system of claim 12, wherein the voltage control unit comprises:
a data comparison unit configured to generate a data comparison signal by comparing the plurality of read data with the write data; and
a decoding unit configured to generate one of the level decrease signal and the level increase signal based on the data comparison signal.

16. The system of claim 15, wherein the data comparison unit comprises:
a register configured to store the write data;
a first comparator configured to compare the write data outputted from the register with the plurality of read data outputted to from the memory module; and
a second comparator configured to generate the data comparison signal based on the comparison result of the first comparator.

17. A power supply voltage setting method of a memory device, comprising:
transmitting data from a controller to the memory device, and storing the data in the memory device;
outputting data stored in the memory device;
comparing the data transmitted to the memory device with the data outputted from the memory device; and
controlling a level of a power supply voltage supplied to the memory device according to a result of the comparing of the data transmitted to the memory device with the data outputted from the memory device.

18. The method of claim 17, wherein the controlling of the level of the power supply voltage includes decreasing the level of the power supply voltage when the data transmitted to the memory device and the data outputted from the memory device are substantially the same.

19. The method of claim 18, wherein the controlling of the level of the power supply voltage further includes increasing the level of the power supply voltage when the data transmitted to the memory device and the data outputted from the memory device are different from each other.

20. The method of claim 17, further comprising storing the data transmitted to the memory device in the controller.
